(19) United States
(12) Patent Application Publication
(10) Pub. No.: US 2026/0173879 A1
(43) Pub. Date: Jun. 18, 2026

(54) TESTING CORE DIE THROUGH A SCRIBE LANE WITH MECHANICAL STRESS-FREE ACCESS FROM A SEAL RING

(71) Applicant: QUALCOMM Incorporated, San Diego, CA (US)

(72) Inventors: Mustafa BADAROGLU, San Diego, CA (US); Roger BOOTH, San Diego, CA (US); Xiaonan CHEN, San Diego, CA (US); Woo Tag KANG, San Diego, CA (US); Zhongze WANG, San Diego, CA (US); Periannan CHIDAMBARAM, San Diego, CA (US)

(21) Appl. No.: 18/981,259

(22) Filed: Dec. 13, 2024

(51) Int. Cl. H01L 23/58; H01L 21/66; H01L 23/528

(52) U.S. Cl. CPC H10W 42/00; H10P 74/273; H10W 20/43

(57) ABSTRACT

A die is described. The die includes a first seal ring on a periphery of the die, which encloses a core of the die. The die also includes one or more bridge interconnect structures across the first seal ring to route a signal from a test pad outside of the first seal ring to a circuit in the core.

### BACKGROUND

### Field

Aspects of the present disclosure relate to semiconductor devices and, more particularly, to testing of a core die through a scribe lane with mechanical stress-free access from a seal ring.

### BACKGROUND

Stringent electrical operational specifications help address system redundancy, provide greater resistance to electrical and software faults, and improve system monitoring. For example, a cell phone may integrate an application processor, such as a system-on-chip (SoC) including a central processing unit (CPU), a graphics processing unit (GPU), and a neural processing unit (NPU). State of the art three-dimensional (3D) stacked packages may implement an application processor. These 3D stacked packages may be formed using wafer-to-wafer, die-to-wafer, or die-to-die stacking of a multitude of wafers. Unfortunately, fine-pitch stacking structures in a core die restrict test pad placement for testing the circuits of the core die area at the wafer-level. A process and structure to enable core die testing using a mechanical, stress-free structure, is desired.

### SUMMARY

A die is described. The die includes a first seal ring on a periphery of the die, which encloses a core of the die. The die also includes one or more bridge interconnect structures across the first seal ring to route a signal from a test pad outside of the first seal ring to a circuit in the core.

A method for forming a die is described. The method includes forming a first seal ring on a periphery of the die to enclose a core of the die having a circuit in the core. The method also includes forming one or more bridge interconnect structures across the first seal ring. The method further includes routing a signal from a test pad outside of the first seal ring to the circuit in the core through one of the one or more bridge interconnect structures.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), which includes a test pad arrangement for memory cell testing and repair in 3D stacked memory, in accordance with aspects of the present disclosure.

FIG. 2 illustrates a layout view of a bridge interconnect structure for circuit testing in a core die, according to various aspects of the present disclosure.

FIG. 3 illustrates a cross-section view of the bridge interconnect structure for testing circuits in the core die of the die of FIG. 2, according to various aspects of the present disclosure.

FIG. 4 illustrates a cross-section view of the bridge interconnect structure for testing circuits in the core die of the die of FIG. 2, according to various aspects of the present disclosure.

FIG. 5 illustrates a layout view of a bridge interconnect structure for testing circuits in a core die of a die, according to various aspects of the present disclosure.

FIGS. 6A and 6B illustrate cross-section views of the bridge interconnect structure for testing circuits in the core die of the die of FIG. 5, according to various aspects of the present disclosure.

FIG. 7 is a process flow diagram illustrating a method for, according to various aspects of the present disclosure.

FIG. 8 is a block diagram showing an exemplary wireless communications system in which a configuration of the disclosure may be advantageously employed.

FIG. 9 is a block diagram illustrating a design workstation used for circuit, layout, and logic design of a semiconductor component, such as the bridge interconnect structure disclosed herein.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches, repeaters, and/or buffers. As described herein, the term “proximate” used throughout this description means “adjacent, very near, next to, or close to.” As described herein, the term “on” used throughout this description means “directly on” in some configurations, and “indirectly on” in other configurations. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced.

Stringent electrical operational specifications help address system redundancy, provide greater resistance to electrical and software faults, and improve system monitoring. For example, a cell phone may integrate an application processor, such as a system-on-chip (SoC) including a central processing unit (CPU), a graphics processing unit (GPU), and a neural processing unit (NPU). State of the art three-dimensional (3D) stacked packages may implement an application processor. These 3D stacked packages may be formed using wafer-to-wafer, die-to-wafer, or die-to-die stacking of a multitude of wafers. Unfortunately, fine-pitch stacking structures in a core die restrict test pad placement for testing the circuits of the core die area at the wafer-level.

For example, advanced 3D stacking approaches, such as hybrid bonding and fusion bonding, do not allow insertion of test pads in a core die area. In particular, topographical changes on the die surface to enable testing are likely to hinder a fine-pitch 3D and/or flip-chip (interposer) stacking. For example, aluminum (Al) test pads are not preferable due the noted topographical changes of the die surface, which further hinder a fine-pitch 3D and/or flip-chip (interposer) stacking. Additionally, a wafer scribe lane is narrowed as a result of novel dicing techniques such as plasma dicing. Consequently, sufficient scribe lane area to place critical circuits for testing becomes unavailable. As a result, layout dependent effects are not captured when a test structure is placed in the scribe lane.

Furthermore, unreliable sawing persists if there is a connecting interconnect from the scribe lane test pad to the circuit in the core die. Additionally, test pads create parasitic loading and area losses if they are placed on the core die. There is a need to test the circuits at wafer-level in the core die, which generally includes fine-pitch stacking structures that restrict test pad placement. In particular, a process and structure to enable core die testing using a mechanical, moisture-blocking, stress-free structure through a seal ring, is desired.

Various aspects of the present disclosure are directed to testing of a core die through a scribe lane with mechanical stress-free access from a seal ring. In some implementations, a die includes a seal ring surrounding a periphery of the die. Additionally, the die includes a bridge interconnect structure that extends across the seal ring, for example, to a scribe lane outside the seal ring. In some implementations, the bridge interconnect structure routes a signal from a test pad outside of the seal ring to circuits of a core die area within the seal ring.

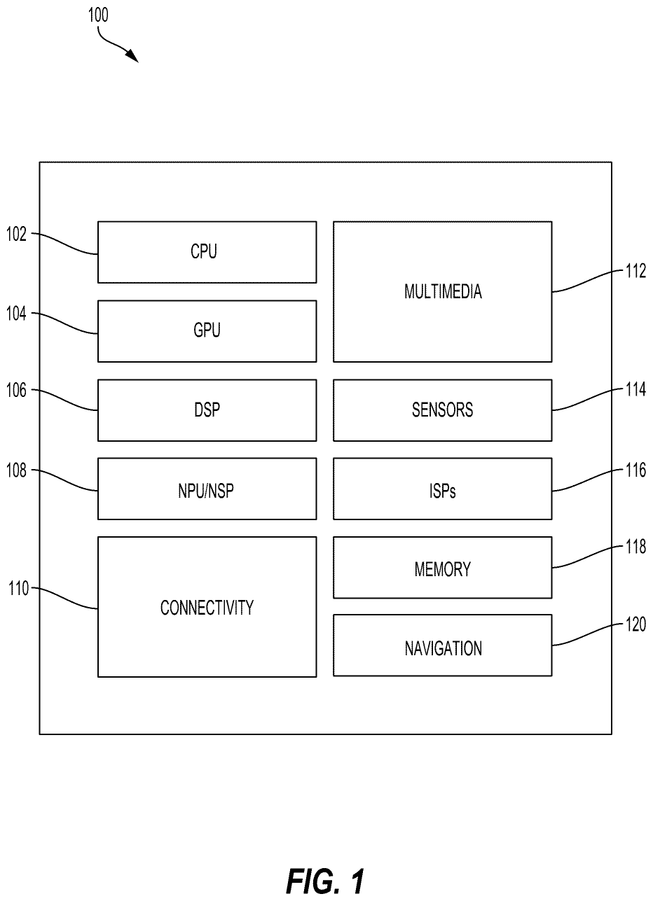

FIG. 1 illustrates an example implementation of a host system-on-chip (SoC) 100, which includes a bridge interconnect structure for core die circuit testing, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU)/neural signal processor (NSP) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU/NSP 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU/NSP 108 may be based on an ARM instruction set.

The manufacture of electrical circuits on semiconductor wafers incorporates circuit testing at several stages of the fabrication process. State of the art three-dimensional (3D) stacked packages may implement the various circuits that form an application process. In practice, these 3D stacked packages are formed using wafer-to-wafer, die-to-wafer, or die-to-die stacking of a multitude of wafers. Unfortunately, fine-pitch stacking structures in a core die restrict test pad placement for testing the circuits of the core die area at the wafer-level.

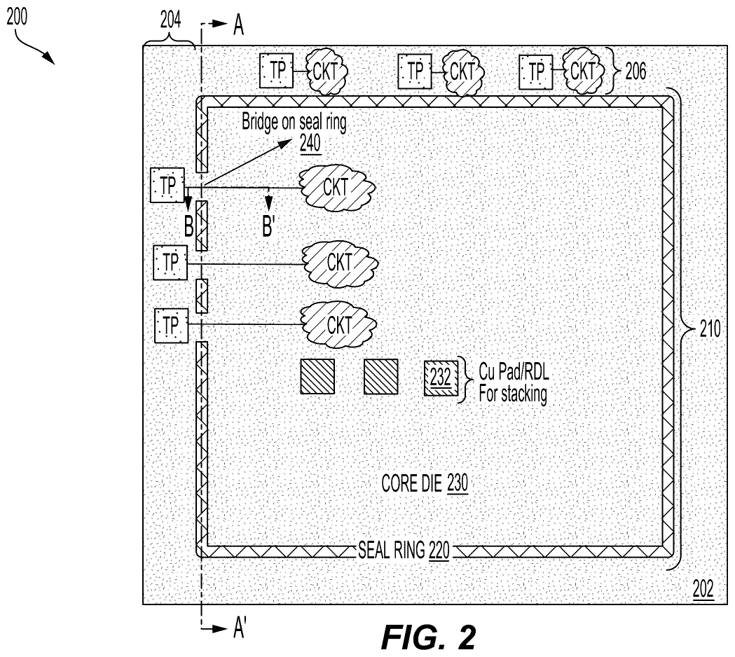

For example, advanced 3D stacking approaches, such as hybrid bonding and fusion bonding, do not allow insertion of test pads in a core die area. In particular, topographical changes on the die surface to enable testing are likely to hinder a fine-pitch 3D and/or flip-chip (interposer) stacking. Additionally, a wafer scribe lane is narrowed as a result of novel dicing techniques such as plasma dicing. Consequently, sufficient scribe lane area to place critical circuits for testing is unavailable. As a result, layout dependent effects are not captured when a test structure is placed in the scribe lane. Additionally, test pads create parasitic loading and area losses on the core die. Various aspects of the present disclosure are directed to core die testing using a mechanical, moisture-blocking, stress-free bridge interconnect structure through a seal ring, for example, as shown in FIG. 2.

FIG. 2 illustrates a layout view 200 of a bridge interconnect structure 240 for testing circuits in a core die 230 of a die 210, according to various aspects of the present disclosure. As shown in FIG. 2, the layout view 200 illustrates a wafer 202 prior to dicing along a scribe lane 204 to form the die 210. This example illustrates a conventional wafer testing structure 206, which provides test pads (TP) coupled to circuits (CKT) in the scribe lane 204 of the wafer 202. The conventional wafer testing structure 206, however, does not enable testing of circuits (CKT) in a core die 230, which is surrounded by a seal ring 220 of the die 210. While the seal ring 220 provides protection of the CKT in the core die 230, the seal ring 220 prevents testing of the CKT in the core die 230. Additionally, fine-pitch stacking structures 232 in the core die 230 restrict test pad placement for testing the CKT of the core die 230 at the wafer-level.

According to various aspects of the present disclosure, a bridge interconnect structure 240 is provided for testing the CKT of the core die 230 at the wafer-level. In this example, the bridge interconnect structure 240 provides mechanical, stress-free access from the seal ring 220 for testing the CKT of the core die 230 through test pads (TP) in the scribe lane 204. In this implementation, the die 210 includes the seal ring 220 surrounding a periphery of the die 210. Additionally, the die 210 includes the bridge interconnect structure 240 that extends across the seal ring 220, for example, to the scribe lane 204 outside the seal ring 220. In this example, the bridge interconnect structure 240 routes a signal from the TP outside of the seal ring 220 to the CKT in the core die 230 within the seal ring 220.

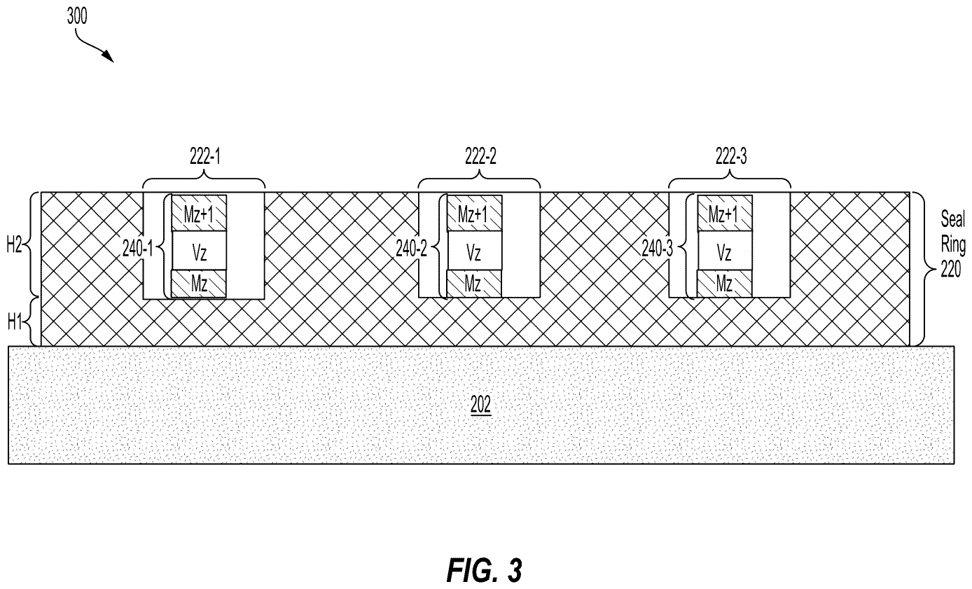

FIG. 3 illustrates a cross-section view 300 of the bridge interconnect structure 240 for testing circuits in the core die 230 of the die 210 of FIG. 2, according to various aspects of the present disclosure. The cross-section view 300 of FIG. 3 is similar to the layout view 200 shown in FIG. 2 and is described using similar reference numbers. FIG. 3 further illustrates the bridge interconnect structure 240 along a cutline AA′ of FIG. 2, according to various aspects of the present disclosure. According to various aspects of the present disclosure, the bridge interconnect structure 240 and the TP may be located vertically or horizontally on the wafer 202 before dicing of the wafer 202 to form the die 210.

As shown in FIG. 3, the seal ring 220 is supported by the wafer 202 and includes partial cavities 222 (222-1, 222-2, 222-3), in which the bridge interconnect structures 240 (e.g., 240-1, 240-2, 240-3) are formed. In this example, the seal ring 220 is shown as having a first height H1 and a second height H2, which are determined according to the depth of the partial cavities 222. Since the partial cavities 222 can accommodate the bridge interconnect structures 240 without breaking the seal ring 220 (i.e., the seal ring 220 remains intact, completely enclosing the core die 230), the effectiveness of the seal ring 220 in protecting the core die 230, for example from moisture, is not compromised. According to various aspects of the present disclosure, the bridge interconnect structures 240 are formed using back-end-of-line (BEOL) metal interconnects.

As described, BEOL interconnects may refer to the conductive interconnect layers (e.g., a first BEOL interconnect layer or metal one (M1), metal two (M2), metal three (M3), metal four (M4), etc.) for electrically coupling to front-end-of-line (FEOL) active devices of an integrated circuit. The various BEOL interconnect layers are formed at corresponding BEOL interconnect levels, in which lower BEOL interconnect levels use thinner metal layers relative to upper BEOL interconnect levels. The BEOL interconnect layers may electrically couple to middle-of-line (MOL) interconnect layers, for example, to connect M1 to an oxide diffusion (OD) layer of an integrated circuit.

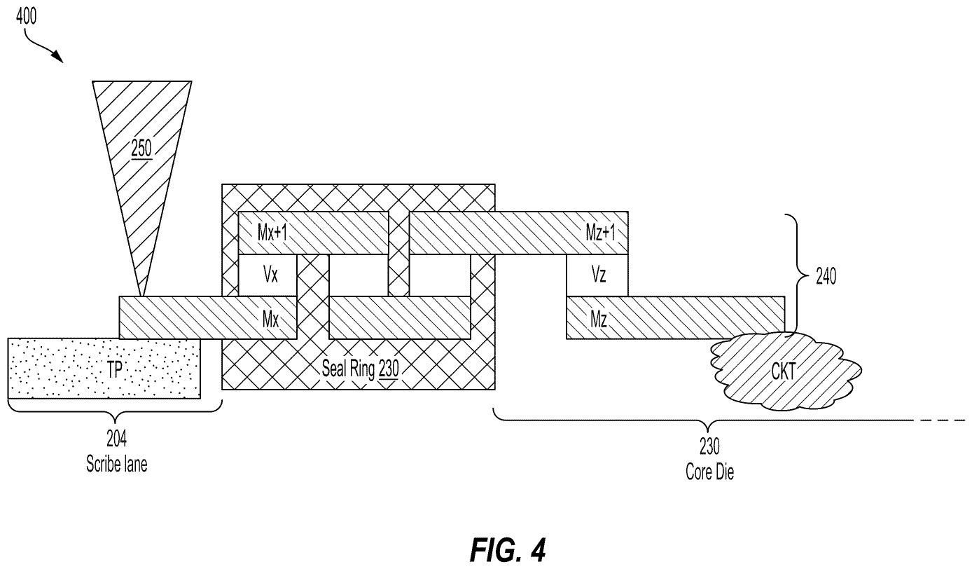

In this example, the bridge interconnect structures 240 include a first metal interconnect Mz supporting a BEOL via Vz, on which a second metal interconnect Mz+1 is formed. In some implementations, the second metal interconnect Mz+1 is a last back-end-of-line (BEOL) metal layer. According to various aspects of the present disclosure, formation of the bridge interconnect structures 240 on the seal ring 220 allows routing of signals from the TP to the CKT in the core die 230 for performing circuit testing. Additionally, singulation of the wafer 202 along the scribe lane 204 does not damage the portion of the bridge interconnect structure 240 proximate the core die 230 because stress caused by the singulation is damped by a via transition fabric, as further illustrated in FIG. 4.

FIG. 4 illustrates a cross-section view 400 of the bridge interconnect structure 240 for testing circuits in the core die 230 of the die 210 of FIG. 2, according to various aspects of the present disclosure. The cross-section view 400 of FIG. 4 is similar to the layout view 200 shown in FIG. 2 and is described using similar reference numbers. FIG. 4 further illustrates the bridge interconnect structure 240 along a cutline BB′ of FIG. 2, according to various aspects of the present disclosure.

As shown in FIG. 4, the bridge interconnect structures 240 is formed using BEOL vias Vz between first and second BEOL interconnects Mz, Mz+1 to provide a via transition fabric. In this example, formation of the bridge interconnect structure 240 on the seal ring 220 allows routing of signals from the TP to the CKT in the core die 230 for performing circuit testing. Additionally, singulation of the wafer 202 is performed using a saw blade/plasma etch 250 along the scribe lane 204 without damaging the core die 230 or the CKT under test within the seal ring 220. In particular, an undulating shape of the bridge interconnect structure 240 formed from BEOL vias Vz between the first and second BEOL interconnects Mz, Mz+1 dampens any pressure caused by the saw blade/plasma etch 250. As a result, portions of the bridge interconnect structure 240 in the core die 230 remain intact because stress caused by the saw blade/plasma etch 250 is damped by the via transition fabric of the bridge interconnect structure 240.

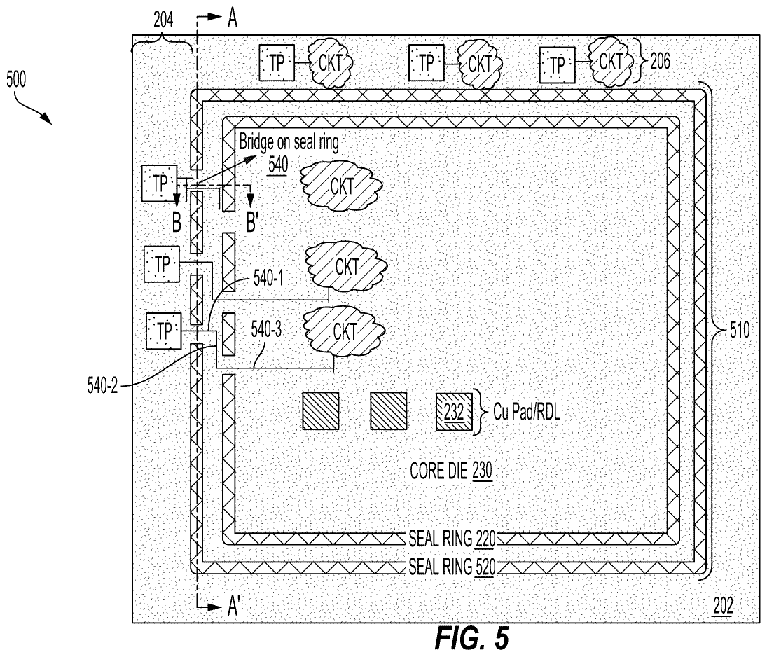

FIG. 5 illustrates a layout view 500 of shifted bridge interconnect structures 540 for testing circuits in the core die 230 of a die 510, according to various aspects of the present disclosure. The layout view 500 of FIG. 5 is similar to the layout view 200 shown in FIG. 2 and is described using similar reference numbers.

As shown in FIG. 5, the layout view 500 illustrates the wafer 202 prior to dicing along a scribe lane 204 to form the die 510. This example illustrates the conventional wafer testing structure 206, which provides the test pads (TP) coupled to circuits (CKT) in a scribe lane 204 of the wafer 202. In this implementation, the die 510 includes the seal ring 220 (e.g., a first seal ring) as well as an additional seal ring 520 (e.g., a second seal ring). Although shown as a single, additional seal ring 520, it should be recognized that any number of seals rings may be utilized to further prevent metal bending and/or delamination in the core die 230.

According to various aspects of the present disclosure, shifted bridge interconnect structures 540 are provided for testing the CKT of the core die 230 at the wafer-level. In this example, the shifted bridge interconnect structures 540 also provide mechanical, moisture-blocking, stress-free access from the seal ring 220 and the additional seal ring 520 for testing the CKT of the core die 230 through TP in the scribe lane 204. In this implementation, the die 510 includes the seal ring 220 surrounding a periphery of the core die 230 and the additional seal ring 520 surrounding the seal ring 220. Additionally, the die 510 includes the shifted bridge interconnect structures 540 that extend across the seal ring 220 and the additional seal ring 520 to the scribe lane 204 outside the additional seal ring 520.

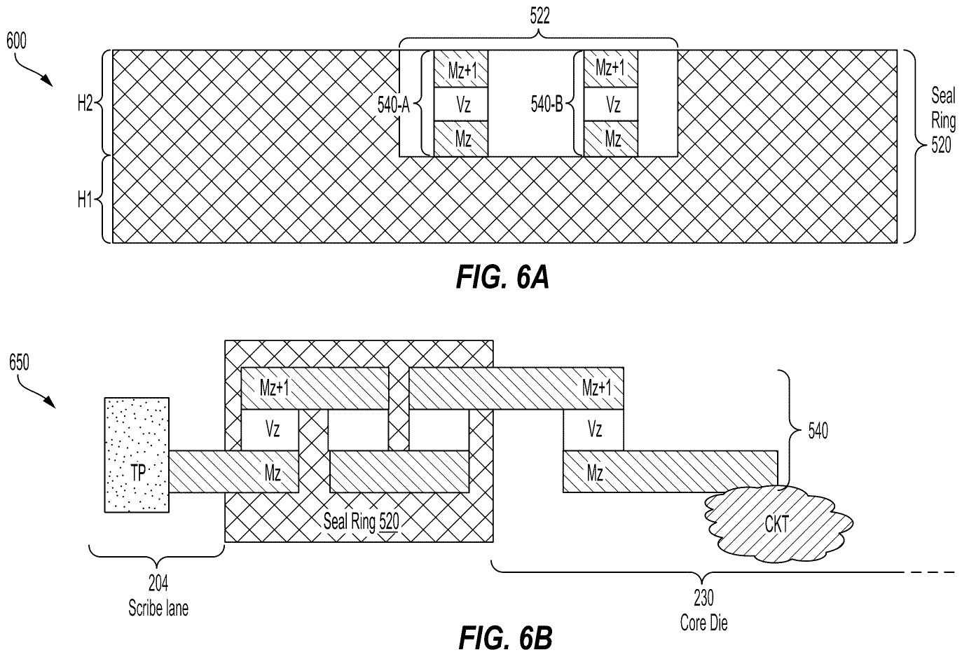

As shown in FIG. 5, the shifted bridge interconnect structures 540 includes various portions for routing testing signals from the TP and between the additional seal ring 520 and the seal ring 220 to the CKT. For example, the shifted bridge interconnect structures 540 may include a first portion 540-1 orthogonal to the additional seal ring 520, a second portion 540-2 between the additional seal ring 520 and the seal ring 220, and a third portion 540-3 orthogonal to the seal ring 220. In this example, the shifted bridge interconnect structures 540 route signals from the TP outside of the additional seal ring 520 to the CKT in the core die 230 within the seal ring 220, which is further illustrated, for example, in FIGS. 6A and 6B.

FIGS. 6A and 6B illustrate cross-section views of the bridge interconnect structure 240 for testing circuits in the core die 230 of the die 510 of FIG. 5, according to various aspects of the present disclosure. A cross-section view 600 of FIG. 6A is similar to the layout view 200 shown in FIG. 2 and is described using similar reference numbers. Similarly, a cross-section view 650 of FIG. 6B is similar to the layout view 200 shown in FIG. 2 and is described using similar reference numbers.

FIG. 6A illustrates the cross-section view 600 of the shifted bridge interconnect structures 540 for testing circuits in the core die 230 of the die 510 of FIG. 5, according to various aspects of the present disclosure. FIG. 6A further illustrates the shifted bridge interconnect structures 540 along a cutline AA′ of FIG. 5, according to various aspects of the present disclosure.

As shown in FIG. 6A, the additional seal ring 520 includes a partial cavity 522 in which the shifted bridge interconnect structures 540 (540-A and 540-B) are formed. In this example, the additional seal ring 520 is shown as having a first height H1 and a second height H2, which are determined according to the depth of the partial cavity 522. According to various aspects of the present disclosure, the shifted bridge interconnect structures 540 are formed using back-end-of-line (BEOL) metal interconnects.

In this example, the shifted bridge interconnect structures 540 also include the first BEOL interconnect Mz supporting the BEOL via Vz, on which the second BEOL interconnect Mz+1 is formed. According to various aspects of the present disclosure, formation of the shifted bridge interconnect structures 540 on the seal ring 220 and the additional seal ring 520 allow routing of signals from the TP to the CKT in the core die 230 for circuit testing. Additionally, singulation of the wafer 202 along the scribe lane 204 does not damage the portion of the shifted bridge interconnect structures 540 proximate the core die 230 because stress caused by the singulation is damped by a via transition fabric, as further illustrated in FIG. 6B.

FIG. 6B illustrates the cross-section view 650 of the shifted bridge interconnect structures 540 for testing circuits in the core die 230 of the die 510 of FIG. 5, according to various aspects of the present disclosure. FIG. 6B further illustrates the shifted bridge interconnect structures 540 along a cutline BB′ of FIG. 5, according to various aspects of the present disclosure.

As shown in FIG. 6B, the shifted bridge interconnect structures 540 are also formed using BEOL vias Vz between the first and second BEOL interconnects Mz, Mz+1 to provide the via transition fabric. In this example, formation of the shifted bridge interconnect structures 540 on the seal ring 220 and the additional seal ring 520 allows routing of signals from the TP to the CKT in the core die 230 for performing circuit testing. Additionally, the undulating shape of the shifted bridge interconnect structures 540 formed from BEOL vias Vx between the first and second BEOL interconnects Mz, Mz+1 dampens any pressure caused by singulation. As a result, any portions of the shifted bridge interconnect structures 540 in the core die 230 remain intact because stress caused by the singulation is damped by the via transition fabric of the shifted bridge interconnect structures 540.

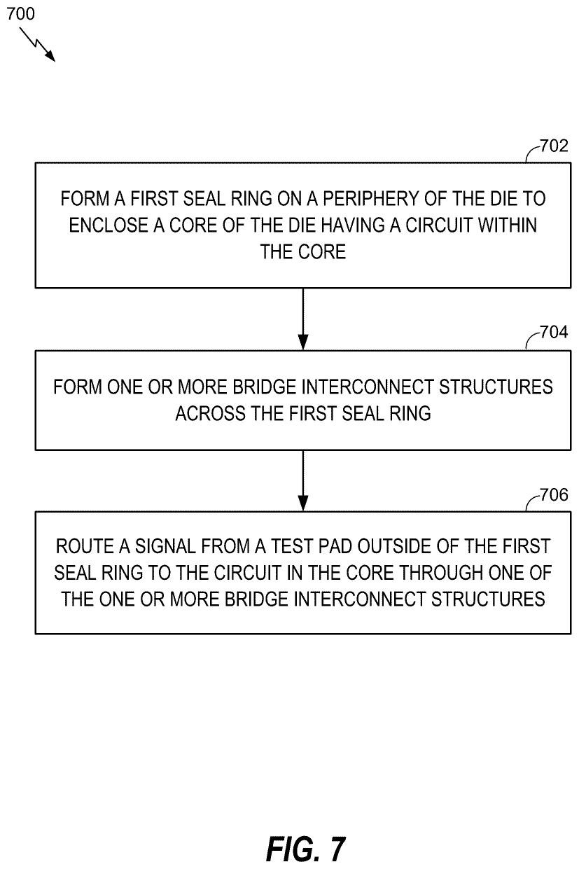

In practice, the seal ring 220 and the additional seal ring 520 provide an enhanced stress protection structure around the core die 230, which protects the core die 230 from damage caused by the singulation (e.g., sawing by the saw blade/plasma etch 250). As a result, the seal ring 220 and the additional seal ring 520 further inhibit routing of test signals from the scribe lane 204 to the core die 230. Additionally, available circuits for placement in the scribe lane for testing is limited due to structures requiring fine-pitch stacking. According to various aspects of the present disclosure, formation of the shifted bridge interconnect structures 540 on the seal rings 220, 520 allows routing of signals from the TP in the scribe lane 204 to the CKT in the core die 230 for performing circuit testing. In this implementation, singulation along the scribe lane 204 does not damage a signal line directed towards the core die 230 because the stress is damped by the via transition fabric of the shifted bridge interconnect structures 540. A process of forming a bridge interconnect structure to enable core die circuit testing is illustrated, for example, in FIG. 7.

FIG. 7 is a process flow diagram illustrating a method 700 for forming a die, according to various aspects of the present disclosure. The method 700 begins at block 702, in which a first seal ring is formed on a periphery of the die to enclose a core of the die having a circuit in the core. For example, as shown in FIG. 2, a core die 230 is surrounded by a seal ring 220 of the die 210. While the seal ring 220 provides protection of the CKT in the core die 230, the seal ring 220 prevents testing of the CKT in the core die 230.

At block 704, one or more bridge interconnect structures are formed across the first seal ring. At block 706, a signal is routed from a test pad outside of the first seal ring to the circuit in the core through one of the one or more bridge interconnect structures. For example, as shown in FIG. 2, a bridge interconnect structure 240 is provided for testing the CKT of the core die 230 at the wafer-level. In this example, the bridge interconnect structure 240 provides mechanical, stress-free access from the seal ring 220 for testing the CKT of the core die 230 through test pads (TP) in the scribe lane 204. In this implementation, the die 210 includes the seal ring 220 surrounding a periphery of the die 210. Additionally, the die 210 includes the bridge interconnect structure 240 that extends across the seal ring 220, for example, to the scribe lane 204 outside the seal ring 220. In this example, the bridge interconnect structure 240 routes a signal from the TP outside of the seal ring 220 to the CKT in the core die 230 within the seal ring 220.

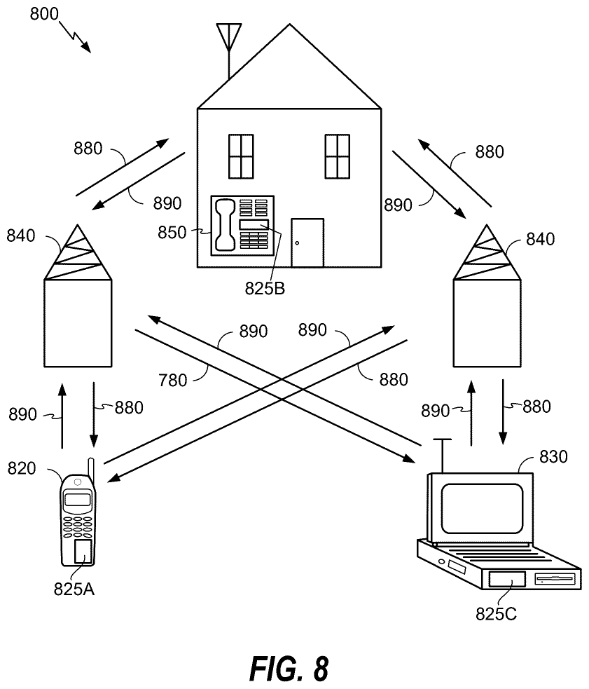

FIG. 8 is a block diagram showing an exemplary wireless communications system 800 in which a configuration of the disclosure may be advantageously employed. For purposes of illustration, FIG. 8 shows three remote units 820, 830, and 850, and two base stations 840. It will be recognized that wireless communications systems may have many more remote units and base stations. Remote units 820, 830, and 850 include integrated circuit (IC) devices 825A, 825C, and 825B that include the disclosed bridge interconnect structure to enable core die circuit testing in 3D stacked package for improved performance. It will be recognized that other devices may also include the disclosed bridge interconnect structure to enable core die circuit testing in 3D stacked package, such as the base stations, switching devices, and network equipment. FIG. 8 shows forward link signals 880 from the base stations 840 to the remote units 820, 830, and 850, and reverse link signals 890 from the remote units 820, 830, and 850 to the base stations 840.

In FIG. 8, remote unit 820 is shown as a mobile telephone, remote unit 830 is shown as a portable computer, and remote unit 850 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 8 illustrates remote units according to aspects of the present disclosure, the disclosure is not limited to these exemplary illustrated units. Aspects of the present disclosure may be suitably employed in many devices, which include the disclosed bridge interconnect structure to enable core die circuit testing in 3D stacked packages.

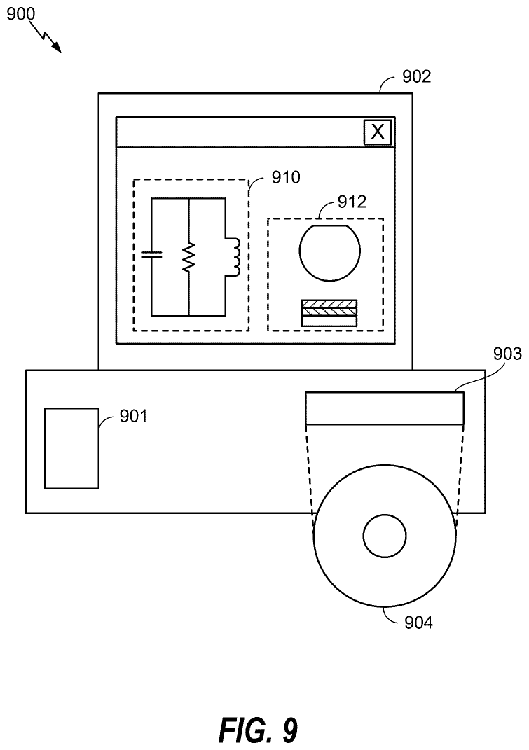

FIG. 9 is a block diagram illustrating a design workstation used for circuit, layout, and logic design of a semiconductor component, such as the vertical bank redundancy in 3D stacked dynamic random-access memory (DRAM) for improved yield disclosed above. A design workstation 900 includes a hard disk 901 containing operating system software, support files, and design software such as Cadence or OrCAD. The design workstation 900 also includes a display 902 to facilitate design of a circuit 910 or an integrated circuit (IC) component 912, such as bridge interconnect structure to enable core die circuit testing in 3D stacked packages. A storage medium 904 is provided for tangibly storing the design of the circuit 910 or the IC component 912 (e.g., the bridge interconnect structure to enable core die circuit testing). The design of the circuit 910 or the IC component 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit 910 or the IC component 912 by decreasing the number of processes for designing semiconductor wafers.

Implementation examples are described in the following numbered clauses:
1. A die, comprising:
   a first seal ring on a periphery of the die, enclosing a core of the die; and
   one or more bridge interconnect structures across the first seal ring to route a signal from a test pad outside of the first seal ring to a circuit in the core.
2. The die of clause 1, in which the one or more bridge interconnect structures comprise:
   a first metal interconnect Mz;
   a metal via Vz on the first metal interconnect Mz; and
   a second metal interconnect Mz+1 on the metal via Vz.
3. The die of any of clauses 1 or 2, further comprising a second seal ring surrounding the first seal ring.
4. The die of clause 3, further comprising a shifted bridge interconnect structure across the first seal ring and the second seal ring to route the signal from the test pad outside of the second seal ring to the circuit of the core inside the first seal ring.
5. The die of clause 4, in which the shifted bridge interconnect structure comprises:
   a first portion orthogonal to the second seal ring;
   a second portion between the second seal ring and the first seal ring; and
   a third portion orthogonal to the first seal ring.
6. The die of clause 5, in which the first portion is coupled to the test pad outside of the second seal ring and the third portion is coupled to the circuit of the core in the first seal ring.
7. The die of any of clauses 1-6, in which the first seal ring comprises a plurality of partial cavities.
8. The die of clause 7, in which the one or more bridge interconnect structures are formed in one of the plurality of partial cavities.
9. The die of any of clauses 1-8, in which the one or more bridge interconnect structures are orthogonal to the first seal ring.
10. The die of any of clauses 1-9, in which the one or more bridge interconnect structures comprise a last back-end-of-line (BEOL) metal layer.
11. A method for forming a die, comprising:
   forming a first seal ring on a periphery of the die to enclose a core of the die having a circuit in the core;
   forming one or more bridge interconnect structures across the first seal ring; and
   routing a signal from a test pad outside of the first seal ring to the circuit in the core through one of the one or more bridge interconnect structures.
12. The method of clause 11, in which the one or more bridge interconnect structures comprise:
   a first metal interconnect Mz;
   a metal via Vz on the first metal interconnect Mz; and
   a second metal interconnect Mz+1 on the metal via Vz.
13. The method of any of clauses 11 or 12, further comprising forming a second seal ring surrounding the first seal ring.
14. The method of clause 13, further comprising forming a shifted bridge interconnect structures across the first seal ring and the second seal ring to route the signal from the test pad outside of the second seal ring to the circuit of the core inside the first seal ring.
15. The method of clause 14, in which the shifted bridge interconnect structures comprises:
   a first portion orthogonal to the second seal ring;
   a second portion between the second seal ring and the first seal ring; and
   a third portion orthogonal to the first seal ring.
16. The method of clause 15, in which the first portion is coupled to the test pad outside of the second seal ring and the third portion is coupled to the circuit in the core of the die and enclosed by the first seal ring.
17. The method of any of clauses 11-16, in which the first seal ring comprises a plurality of partial cavities.
18. The method of clause 17, in which the one or more bridge interconnect structures are formed in one of the plurality of partial cavities.
19. The method of any of clauses 11-18, in which the one or more bridge interconnect structures are formed orthogonal to the first seal ring.
20. The method of any of clauses 11-19, in which the one or more bridge interconnect structures comprise a last back-end-of-line (BEOL) metal layer.

For a firmware and/or software implementation, the methodologies may be implemented with modules (e.g., procedures, functions, etc.) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A die, comprising:
a first seal ring on a periphery of the die, enclosing a core of the die; and
one or more bridge interconnect structures across the first seal ring to route a signal from a test pad outside of the first seal ring to a circuit in the core.

2. The die of claim 1, in which the one or more bridge interconnect structures comprise:
a first metal interconnect Mz;
a metal via Vz on the first metal interconnect Mz; and
a second metal interconnect Mz+1 on the metal via Vz.

3. The die of claim 1, further comprising a second seal ring surrounding the first seal ring.

4. The die of claim 3, further comprising a shifted bridge interconnect structure across the first seal ring and the second seal ring to route the signal from the test pad outside of the second seal ring to the circuit of the core inside the first seal ring.

5. The die of claim 4, in which the shifted bridge interconnect structure comprises:
a first portion orthogonal to the second seal ring;
a second portion between the second seal ring and the first seal ring; and
a third portion orthogonal to the first seal ring.

6. The die of claim 5, in which the first portion is coupled to the test pad outside of the second seal ring and the third portion is coupled to the circuit of the core in the first seal ring.

7. The die of claim 1, in which the first seal ring comprises a plurality of partial cavities.

8. The die of claim 7, in which the one or more bridge interconnect structures are formed in one of the plurality of partial cavities.

9. The die of claim 1, in which the one or more bridge interconnect structures are orthogonal to the first seal ring.

10. The die of claim 1, in which the one or more bridge interconnect structures comprise a last back-end-of-line (BEOL) metal layer.

11. A method for forming a die, the method comprising:
forming a first seal ring on a periphery of the die to enclose a core of the die having a circuit in the core;
forming one or more bridge interconnect structures across the first seal ring; and
routing a signal from a test pad outside of the first seal ring to the circuit in the core through one of the one or more bridge interconnect structures.

12. The method of claim 11, in which the one or more bridge interconnect structures comprise:
a first metal interconnect Mz;
a metal via Vz on the first metal interconnect Mz; and
a second metal interconnect Mz+1 on the metal via Vz.

13. The method of claim 11, further comprising forming a second seal ring surrounding the first seal ring.

14. The method of claim 13, further comprising forming a shifted bridge interconnect structures across the first seal ring and the second seal ring to route the signal from the test pad outside of the second seal ring to the circuit of the core inside the first seal ring.

15. The method of claim 14, in which the shifted bridge interconnect structures comprises:
a first portion orthogonal to the second seal ring;
a second portion between the second seal ring and the first seal ring; and
a third portion orthogonal to the first seal ring.

16. The method of claim 15, in which the first portion is coupled to the test pad outside of the second seal ring and the third portion is coupled to the circuit in the core of the die and enclosed by the first seal ring.

17. The method of claim 11, in which the first seal ring comprises a plurality of partial cavities.

18. The method of claim 17, in which the one or more bridge interconnect structures are formed in one of the plurality of partial cavities.

19. The method of claim 11, in which the one or more bridge interconnect structures are formed orthogonal to the first seal ring.

20. The method of claim 11, in which the one or more bridge interconnect structures comprise a last back-end-of-line (BEOL) metal layer.
